(19) United States
(12) Patent Application Publication
(10) Pub. No.: US 2024/0081151 A1
(43) Pub. Date: Mar. 7, 2024

(54) ELECTROMECHANICAL CONVERSION ELEMENT, METHOD FOR MANUFACTURING SAME, AND LIQUID DISCHARGE HEAD

(71) Applicant: Konica Minolta, Inc., Tokyo (JP)

(72) Inventors: Hideki MASHIMA, Sagamihara-shi, Kanagawa (JP); Shintaro HARA, Omuta-shi, Fukuoka (JP)

(21) Appl. No.: 18/272,527

(22) PCT Filed: Feb. 5, 2021
(86) PCT No.: PCT/JP2021/004335

§ 371 Date: Jul. 14, 2023

(51) Int. Cl. H10N 30/00; H10N 30/093; H10N 30/853

(52) U.S. Cl. CPC H10N 30/10516; H10N 30/093; H10N 30/8554; B41J 2/14233

(57) ABSTRACT

An electromechanical conversion element includes: a first electrode, an electromechanical conversion layer, and a second electrode provided on a substrate; a first high-temperature durable layer that contains a metal oxide between the first electrode and the electromechanical conversion layer; and a second high temperature durable layer that containing a metal oxide between the electromechanical conversion layer and the second electrode. The electromechanical conversion layer contains a perovskite-type crystal. Upon diffraction peak intensities of a (001) plane, a (101) plane, and a (111) plane in X-ray diffraction measurement of the electromechanical conversion layer being I(001), I(101), and I(111), respectively, a degree of orientation of the (001) plane represented by {I(001))/(I(001)+I(101)+I(111)}×100% is 99.0% or more.

### TECHNICAL FIELD

The present invention relates to an electromechanical conversion element, a method of manufacturing the same, and a liquid ejection head. More specifically, the present invention relates to an electromechanical conversion element in which a decrease in the amount of displacement of a piezoelectric material over time is suppressed when the electromechanical conversion element is continuously pulse-driven for a long period of time in a high-temperature environment, a method for manufacturing the electromechanical conversion element, and a liquid ejection head.

### BACKGROUND ART

In recent years, lead-based piezoelectric materials such as lead zirconate titanate (Pb (Zr, Ti) O₃) and lead-free piezoelectric materials have been used as electromechanical conversion elements for application to driving elements, sensors, and the like. Such a piezoelectric material is expected to be applied to a micro electro mechanical systems (MEMS) element by being formed as a thin layer on a substrate of silicon (Si) etc.

In manufacturing the MEMS element, high-accuracy processing using a semiconductor process technology such as photolithography can be applied. Therefore, the size of the element can be reduced, and the density of the element can be increased. In particular, collectively manufacturing elements at a high density on a relatively large Si wafer having a diameter of 6 inches or 8 inches can significantly reduce costs as compared with single wafer manufacturing in which elements are individually manufactured.

In addition, due to the thinning of a piezoelectric material and the use of MEMS in a device, the electromechanical conversion efficiency is improved, and thus new added values such as the improvement of the sensitivity and characteristics of the device are also produced. For example, in a heat sensor, measurement sensitivity can be increased by a reduction in thermal conductance due to the use of MEMS. In addition, in an inkjet head for a printer, it is possible to perform high-definition patterning due to an increase in the density of nozzles. In addition, a high piezoelectric constant d31 is required for an electromechanical conversion layer containing a piezoelectric material required for such a device, for example, an electromechanical conversion layer of a method called a bend mode.

When the electromechanical conversion layer is used as a MEMS driving element, the electromechanical conversion layer needs to be formed with a thickness of, for example, 1 to 10 lam in order to satisfy a required displacement generating force, although it depends on a device to be designed. In order to form an electromechanical conversion layer on a substrate such as Si, a chemical layer formation method such as a chemical vapor deposition (CVD) method, a physical method such as a sputtering method or an ion plating method, and a growth method in a liquid phase such as a sol-gel method are known. It is important to find layer forming conditions for obtaining a layer having necessary performance in accordance with these layer forming methods.

As the piezoelectric material, lead zirconate titanate (PZT) having a perovskite structure, which has ferroelectric properties and favorable piezoelectric properties, is generally used. In addition, Patent Document 1 and Patent Document 2 disclose that various metals or oxides thereof can be used for upper and lower electrodes that apply a voltage to the piezoelectric material in a thickness direction.

In addition, Patent Document 1 to Patent Document 5 disclose the widespread use of a thin layer-shaped electromechanical conversion element using a piezoelectric material having a perovskite structure.

For example, when the thin layer-shaped electromechanical conversion element is used in an inkjet head, if the amount of displacement of the piezoelectric material decreases when the piezoelectric material is continuously pulse-driven for a long period of time, the ejection speed of ink droplets from the inkjet head also changes with time. From the viewpoint of increasing the durability of the thin layer-shaped electromechanical conversion element, the piezoelectric material is required to have a small change in displacement amount due to long-term use.

In particular, according to the findings of the present inventors, when a piezoelectric material having a perovskite structure is continuously pulse-driven under a high-temperature environment for a long period of time, the decrease in the displacement amount is significant.

That is, in driving at the room temperature, the layer characteristics of the PZT can secure a desired ink ejection amount and a desired ejection speed at the time of ink ejection. However, when ink is heated in order to eject high-viscosity ink, the electromechanical conversion layer is also heated. At a high temperature of 50° C. or more, there has been a problem that when pulse driving is performed continuously for a long period of time, the piezoelectricity decreases, and sufficient ejection performance cannot be ensured.

### CITATION LIST

### Patent Literature

[Patent Document 1] Japanese Unexamined Patent Publication No. 2016-36006
[Patent Document 2] Japanese Unexamined Patent Publication No. 2005-228838
[Patent Document 3] Japanese Unexamined Patent Publication No. 2004-47928
[Patent Document 4] Japanese Unexamined Patent Publication No. 2004-186646
[Patent Document 5] Japanese Unexamined Patent Publication No. 2005-119166

### SUMMARY OF INVENTION

### Technical Problem

The present invention has been made in view of the above problems and circumstances. An object of the present invention is to provide an electromechanical conversion element in which a decrease over time in the displacement amount of a piezoelectric material is suppressed when the element is continuously pulse-driven under a high-temperature environment for a long period of time, a method for producing the same, and a liquid ejection head including the electromechanical conversion element.

### Solution to Problem

In order to solve the above problems, the inventors have examined the causes of the above problems and other issues. As a result, the present inventors have found that, in an electromechanical conversion element including a first electrode, a first high-temperature durable layer, an electromechanical conversion layer, a second high-temperature durable layer, and a second electrode in this order, in a case where the electromechanical conversion layer contains a perovskite-type crystal, and the crystal has a (001) plane that is preferentially oriented, the object can be achieved.

That is, the aforementioned problem is solved by the following means according to the present invention.
1. An electromechanical conversion element including:
   a first electrode, an electromechanical conversion layer, and a second electrode provided on a substrate;
   a first high-temperature durable layer that contains a metal oxide between the first electrode and the electromechanical conversion layer; and
   a second high-temperature durable layer that containing a metal oxide between the electromechanical conversion layer and the second electrode,
   wherein the electromechanical conversion layer contains a perovskite-type crystal, and
   upon diffraction peak intensities of a (001) plane, a (101) plane, and a (111) plane in X-ray diffraction measurement of the electromechanical conversion layer being I(001), I(101), and I(111), respectively, a degree of orientation of the (001) plane represented by {I(001))/(I(001)+I(101)+I(111)}×100% is 99.0% or more.
2. The electromechanical conversion element according to item 1, wherein metal oxides contained in the first high-temperature durable layer and the second high-temperature durable layer each independently contain lanthanum lead titanate (PLT), strontium ruthenate (SRO), lanthanum nickelate (LNO), or lead titanate (PT).
3. The electromechanical conversion element according to item 1 or 2, wherein the perovskite type crystal contains lead zirconate titanate (PTZ).
4. The electromechanical conversion element according to any one of items 1 to 3, wherein, upon a residual polarization at 50° C. being denoted by Pr(50° C.) [μC/cm²] and a residual polarization at 20° C. being denoted by Pr(20° C.) [μC/cm²], Expression 1 is satisfied:

Pr(50° C.)/Pr(20° C.)≥1.00. (Expression 1):
5. The electromechanical conversion element according to any one of items 1 to 4, wherein, upon a residual polarization at 85° C. being denoted by Pr(85° C.) [μC/cm²] and a residual polarization at 20° C. being denoted by Pr(20° C.) [μC/cm²], Expression 2 is satisfied:

Pr(85° C.)/Pr(20° C.)≥0.90. (Expression 2):
6. The electromechanical conversion element according to any one of items 1 to 5, wherein relative dielectric constants of the first high-temperature durable layer and the second high-temperature durable layer are both smaller than a relative dielectric constant of the electromechanical conversion layer.
7. A method of manufacturing the electromechanical conversion element according to any one of items 1 to 6, including:
   forming an electromechanical conversion layer on the first high-temperature durable layer, and
   in the forming of the electromechanical conversion layer, heating the electromechanical conversion layer to 500° C. or higher and then cooling the electromechanical conversion layer to 300° C. or lower is repeated twice or more to form the electromechanical transducer layer.
8. A liquid ejection head including the electromechanical conversion element according to any one of items 1 to 6.

### Advantageous Effects of Invention

According to the present invention, it is possible to provide an electromechanical conversion element in which a decrease over time in the displacement amount of a piezoelectric material when the electromechanical conversion element is pulse-driven continuously for a long period of time under a high-temperature environment is suppressed, a method for producing the same, and a liquid ejection head including the electromechanical conversion element.

An expression mechanism or an action mechanism of the effect of the present invention is not clear, but is assumed as follows.

It is generally known that the mechanism of exhibiting piezoelectricity depends on the magnitude of the polarization of the B site of the perovskite structure. The degree of polarization is indicated by the magnitude of the value of the residual polarization Pr, and a larger value indicates higher piezoelectricity.

In particular, in a case where the piezoelectric material is preferentially oriented in a (001) plane in the same direction as the application direction of the voltage, the piezoelectric constant d₃₁ increases, and the electromechanical transducer functions efficiently. Since the (101) or (111) plane directions that are hetero phases do not coincide with the direction of application of an electric field, they do not contribute a lot to the piezoelectric characteristics.

When a large electric field is applied, piezoelectricity is exhibited by an electrostrictive effect due to rotation of polarization or the like. However, since the polarization is repeatedly moved, fatigue of the polarization or the like is caused, and loss of piezoelectricity occurs in continuous driving. In particular, in driving under a high-temperature condition, the deterioration of polarization is considered to be likely to proceed. Therefore, it is surmised that only the alignment of (001) plane having no polarization rotation or the like is advantageous for deterioration during continuous driving.

In addition, deterioration of the piezoelectric material at the electrode interface is considered as another factor causing deterioration of polarization. Although the mechanism has not yet been completely clarified, for example, charge exchange is performed by pulse driving of the element. This leads to a model in which oxygen defects and the like occur in the perovskite structure and the degradation of polarization progresses, such that the value of the residual polarization Pr decreases. Further, it is also considered that the progress of diffusion of some elements contained in the electrode under a driving condition at a high temperature is a deterioration factor of the piezoelectric material.

Therefore, it is presumed that the introduction of the high-temperature durable layer which relaxes the interaction at the interface between the electromechanical conversion layer and the electrode and suppresses the deterioration of the polarization of the electromechanical conversion layer exhibits a remarkable effect under the high-temperature driving condition.

### BRIEF DESCRIPTION OF DRAWINGS

FIG. 1 This is an example of a cross-sectional view of the electromechanical conversion element according to the present invention.

FIG. 2 This is an example of polarization—electric field hysteresis of the electromechanical conversion element of the present invention.

FIG. 3 This is an example of temperature dependence of residual polarization in electromechanical conversion elements of the present invention and a comparative example.

FIG. 4 This is an example of cross-sectional view of a liquid ejection head of the present invention.

FIG. 5 This is an example of an image recording apparatus equipped with the liquid ejection head of the present invention.

FIG. 6 This is an example of an image recording apparatus equipped with the liquid ejection head of the present invention.

FIG. 7 This is an example of the number of heating and cooling cycles of the electromechanical conversion layer and the orientation degree (%) of the (001) plane in the XRD measurement.

FIG. 8 This is a graph showing a relationship between the number of applied pulses and an ejection speed.

### DESCRIPTION OF EMBODIMENTS

According to an aspect of the present invention, there is provided an electromechanical conversion element including a first electrode, an electromechanical conversion layer, and a second electrode that are provided on a substrate. A first high-temperature durable layer containing a metallic oxide is provided between the first electrode and the electromechanical conversion layer. A second high-temperature durable layer containing a metallic oxide is provided between the electromechanical conversion layer and the second electrode. The electromechanical conversion layer contains a perovskite-type crystal. In a case where diffraction peak intensities of a (001) plane, a (101) plane, and a (111) plane of the electromechanical conversion layer in an X-ray diffraction measurement are represented by I(001), I(101), and I(111), respectively, a degree of orientation of the (001) plane represented by {I(001)/I(001)+I(101)+I(111))}×100% is 99.0% or more. This feature is a technical feature common to or corresponding to the following embodiments (modes).

As an embodiment of the present invention, it is preferable that the metal oxides contained in the first high-temperature durable layer and the second high-temperature durable layer each independently contain lead lanthanum titanate (PLT), strontium ruthenate (SRO), lanthanum nickelate (LNO), or lead titanate (PT). As a result, good adhesion between the upper and lower electrodes and the respective high-temperature durable layers can be obtained. In addition, as a buffer layer with the electromechanical conversion layer, deterioration such as an oxygen defect of the electromechanical conversion layer during continuous driving is prevented. Thus, the polarization can be maintained, and a decrease in the residual polarization Pr can be prevented.

Further, the first high-temperature durable layer on the lower electrode also has a function of a seed layer that promotes crystal growth of the electromechanical transducer layer, and has an effect of providing good crystallinity and piezoelectric characteristics of the electromechanical conversion layer. In addition to the above effect, the second high-temperature durable layer at the interface with the upper electrode has an effect that a current leak path from the crystal grain boundary is less likely to occur because the crystallinity is discontinuous.

In an embodiment of the present invention, the perovskite-type crystal preferably contains lead zirconate titanate (PZT). As a result, since high piezoelectric characteristics can be exhibited, a high displacement amount can be obtained, and the electromechanical conversion element having high performance is obtained.

Further, in the present invention, when the residual polarization at 50° C. is defined as Pr(50° C.) [μC/cm²] and the residual polarization at 20° C. is defined as Pr(20° C.) [μC/cm²], it is preferable that Expression 1 is satisfied. As a result, since the polarization is maintained in a large state, high piezoelectric properties are generated.

In an embodiment of the present invention, when the residual polarization at 85° C. is defined as Pr(85° C.) [μC/cm²] and the residual polarization at 20° C. is defined as Pr(20° C.) [μC/cm²], it is preferable that Expression 2 is satisfied because a decrease in polarization is suppressed and a decrease in piezoelectric properties is also reduced.

Further, it is preferable that the relative dielectric constants of the first high-temperature durable layer and the second high-temperature durable layer are both smaller than the relative dielectric constant of the electromechanical conversion layer. As compared with an electromechanical conversion element formed of only an electromechanical conversion layer, there is an effect that a capacity decreases, and there is an effect that a load during driving is reduced and deterioration of a driving life can be alleviated.

Furthermore, a method for producing the electromechanical conversion element to produce the electromechanical conversion element of the present invention includes an electromechanical conversion layer film-forming step to form an electromechanical conversion layer on the first high temperature. In the electromechanical conversion layer film-forming step, the electromechanical conversion layer is formed by repeating twice or more a step of heating the electromechanical conversion layer to 500° C. or more and then cooling the electromechanical conversion layer to 300° C. or less. Thus, the degree of orientation of the (001) plane can be improved, and an electromechanical conversion layer having high crystallinity with a single orientation can be provided.

The electromechanical conversion element according to the present invention can be suitably included in a liquid ejection (discharge) head.

Hereinafter, the present invention, the constituent elements thereof, and modes and aspects for carrying out the present invention will be described in detail. In the present application, “to” is used to mean that numerical values described before and after “to” are included as a lower limit value and an upper limit value.

<<Electromechanical Conversion Element>>

According to an aspect of the present invention, there is provided an electromechanical conversion element including a first electrode, an electromechanical conversion layer, and a second electrode that are provided on a substrate. A first high-temperature durable layer containing a metallic oxide is provided between the first electrode and the electromechanical conversion layer. A second high-temperature durable layer containing a metallic oxide is provided between the electromechanical conversion layer and the second electrode. The electromechanical conversion layer contains a perovskite-type crystal. In a case where diffraction peak intensities of a (001) plane, a (101) plane, and a (111) plane of the electromechanical conversion layer in an X-ray diffraction measurement are represented by I(001), I(101), and I(111), respectively, a degree of orientation of the (001) plane represented by {I(001)/(I(001)+I(101)+I(111))}×100% is 99.0% or more.

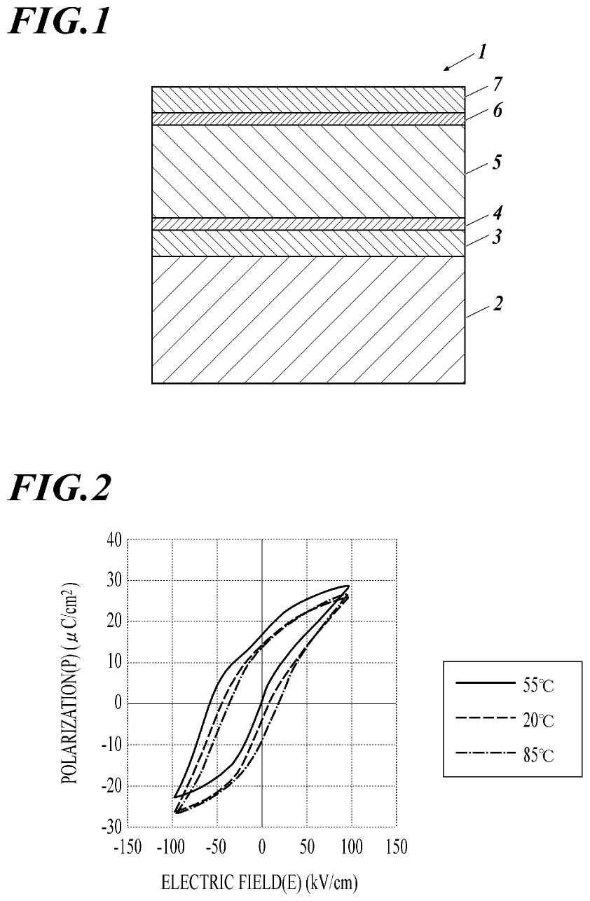

FIG. 1 is an example of a cross-sectional view of an electromechanical conversion element of the present invention. The electromechanical conversion element 1 includes a first electrode 3, a first high-temperature durable layer 4, an electromechanical conversion layer 5, a second high-temperature durable layer 6, and a second electrode 7 on a substrate 2 in this order. In the present invention, the electromechanical conversion layer contains a perovskite-type crystal and has a plane orientation degree of (001) plane of 99.0% or more.

With such a configuration, it is possible to obtain an electromechanical conversion element in which a decrease in the amount of displacement of the piezoelectric material over time is suppressed when the electromechanical conversion element is continuously pulse-driven for a long period of time in a high-temperature environment.

[Electromechanical Conversion Layer]

In the present invention, the electromechanical conversion layer contains a perovskite-type crystal and has a plane orientation degree of (001) plane of 99.0% or more. Furthermore, it is preferable that the perovskite type crystal contains lead zirconate titanate (PZT). By containing lead zirconate titanate (ZT), the degree of orientation of the (001) plane is improved, and an electromechanical conversion layer having high crystallinity of single orientation is obtained. The content of PZT is preferably 90% by mass or more, and the perovskite-type crystal is more preferably composed of PZT.

As the PZT, a crystal made of lead (Pb), zirconium (Zr), titanium (Ti), and oxygen (O) is used. Since PZT exhibits a good piezoelectric effect in a case where it has an ABO 3 type perovskite structure, it is preferable that the crystal orientation of the perovskite is a single phase. A crystal having a pyrochlore structure or a crystal structure having an amorphous structure does not exhibit piezoelectricity, and thus is not preferable because it becomes a factor that inhibits development of favorable piezoelectric characteristics. Since evaporation of Pb easily occurs at the time of layer formation of PZT, it is required to obtain a perovskite crystal by controlling an excess lead composition of a target or setting an optimal layer formation condition.

The shape of the unit lattice of the crystal of PZT having an ABO 3 type perovskite structure changes depending on a ratio of Ti to Zr which are atoms entering a B site. That is, in a case where the amount of Ti is large, the crystal lattice of PZT becomes a tetragonal crystal, and in a case where the amount of Zr is large, the crystal lattice of PZT becomes a rhombohedral crystal.

When the molar ratio of Zr to Ti is around 52:48, both of these crystal structures exist, and a phase boundary having such a composition ratio is called a morphotropic phase boundary (MPB). Since the maximum of piezoelectric characteristics such as a piezoelectric constant, a polarization value, and a dielectric constant is obtained with this MPB composition, a piezoelectric material having the MPB composition is actively used.

Here, in a case where PZT is represented by Pb (ZrₓTi₁₋ₓ)O₃, x is within a range of 0.50 to 0.58, which is the MPB composition or a composition close thereto. Accordingly, higher piezoelectric properties (for example, a high piezoelectric constant d₃₁) can be obtained as compared with a composition other than MPB.

In particular, the molar ratio of Zr to Ti is desirably around 52:48 at which the MPB composition is obtained.

In the present invention, the electromechanical conversion layer 5 has (001) plane of the perovskite phase as the main orientation. That is, in a case where diffraction peak intensities of a (001) plane, a (101) plane, and a (111) plane of the electromechanical conversion layer in an X-ray diffraction measurement are represented by I(001), I(101), and I(111), respectively, a degree of orientation of the (001) plane represented by {I(000/(I(001)+I(101)+4110)}×100% is 99.0% or more. In order to improve the degree of orientation, as described later, in the step of forming the electromechanical conversion layer, it is preferable that a step of heating the electromechanical conversion layer to 500° C. or higher and then cooling the electromechanical conversion layer to 300° C. or lower is repeated two or more times to form the layer.

(Degree of Orientation of (001) Plane in XRD Measurement)

The X-ray diffraction measurement of the electromechanical conversion layer is performed under the following conditions.

In the electromechanical conversion layer 5, in a case where diffraction peak intensities of a (001) plane, a (101) plane, and a (111) plane of the perovskite phase obtained by 2θ/θ measurement of X-ray diffraction (XRD) are respectively represented by I(001), I(101), and I(111), a degree of orientation of the (001) plane represented by {I(000/(I(001)+I(101)+I(111))}×100% is 99.0% or more.

An X-ray diffractometer RINT-TTR III manufactured by Rigaku Corporation is used as a measuring apparatus, and the measurement can be performed under the following conditions.
Out-of-plane Measurement: measurement angle range 10-110° (001)-(004)

(Residual Polarization)

An electromechanical conversion element including an electromechanical conversion layer having an improved single-plane orientation degree in the above (001) plane and high crystallinity in a single orientation can reduce a decrease in residual polarization even at high temperatures. In addition, it is possible to suppress a decrease in the amount of displacement of the piezoelectric material over time when the piezoelectric material is continuously pulse-driven for a long period of time under a high temperature environment.

When the residual polarization at 50° C. is Pr(50° C.) [μC/cm²] and the residual polarization at 20° C. is Pr(20° C.) [μC/cm²], it is preferable that the electromechanical conversion element according to the present invention satisfies Expression 1 below.

Pr(50° C.)/Pr(20° C.)≥1.00 (Expression 1):

When the residual polarization at 85° C. is defined as Pr(85° C.) [μC/cm²] and the residual polarization at 20° C. is defined as Pr(20° C.) [μC/cm²], it is preferable that Expression 2 below is satisfied.

Pr(85° C.)/Pr(20° C.)≥0.90 (Expression 2):

FIG. 2 is an example of polarization-electric field hysteresis of the electromechanical conversion element according to the present invention.

In general, polarization-electric field hysteresis indicating a relationship between polarization (P) and an electric field (E) in an electromechanical element has a shape in which polarization (absolute values) is substantially symmetrical between a positive electric field side and a negative electric field side with respect to a vertical axis (E=0 V). Hereinafter, the polarization-electric field hysteresis is also referred to as P-E hysteresis.

However, it is known that the P-E hysteresis shifts to the + side or the − side in a case where a donor is added to the electromechanical conversion layer. In addition, it is known that a shift of the hysteresis also occurs in a memory element that has been used for a long time while polarization inversion is repeated. In that case, as it is known that the shift amount is reduced when the electrode is changed, a change in hysteresis also occurs depending on the state of the interface with the electrode. The point where the P-E hysteresis intersects the vertical axis (E=0 V) is called the residual polarization Pr, and the point where it intersects the horizontal axis (P=0 RC/cm′) is called the anti-electric field.

Here, Pr relates to the magnitude of the piezoelectric characteristic. It can be said that as the Pr is larger, the piezoelectric characteristic is larger. Therefore, it is important for the performance of the electromechanical conversion element that Pr is large even in the asymmetric hysteresis.

In a case where an electromechanical conversion element is formed by sandwiching the electromechanical conversion layer according to the present invention between a first electrode and a second electrode, the first electrode is used as a common electrode and the second electrode is used as an individual electrode. When a positive electric field driving is applied to the second electrode to drive the second electrode, the electromechanical conversion element has asymmetric P-E hysteresis as shown in FIG. 2. In a case where Pr(+Pr) on the positive electric field side is defined as Pr, it can be seen that Pr changes depending on the temperature used.

In the present invention, no deterioration of Pr is observed at 55° C. due to the effect of the high-temperature durable layer, and substantially the same Pr is maintained even in the high-temperature region of 85° C. Therefore, as defined by Expression 1 and Expression 2, it is considered that having a characteristic of having a small decrease in residual polarization even at a high temperature implies that sufficient durability is maintained even in use in a high temperature region.

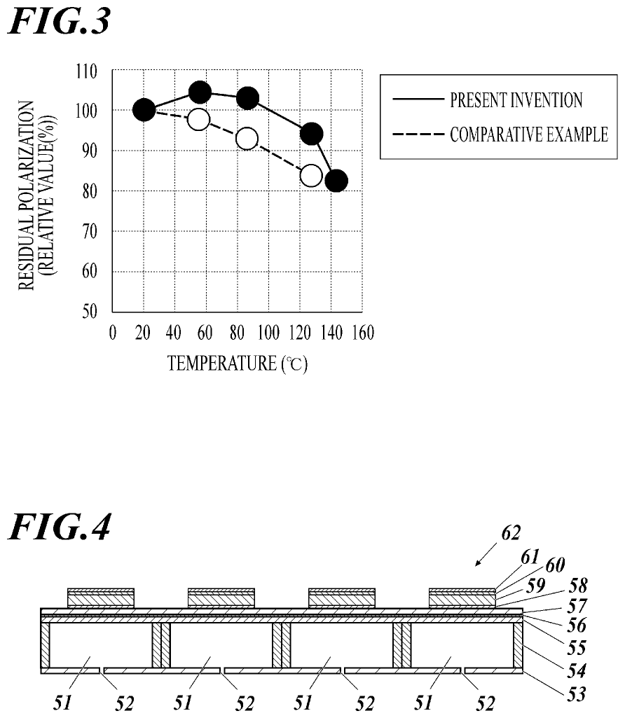

FIG. 3 shows an example of the temperature dependence of residual polarization in the electromechanical conversion element of the present invention and that if the comparative example. As will be described later in the example, the residual polarization Pr substantially equivalent to that at room temperature (20° C.) is maintained even in the high-temperature region.

The residual polarization Pr can be obtained by measuring P-E hysteresis by applying a triangular wave pf −120 to +120 kV/cm at 1 kHz frequency, using a ferroelectric tester precision LCII manufactured by Radiant Technology Inc. [First High-Temperature Durable Layer and Second High-Temperature Durable Layer]

It is preferable that the metal oxides contained in the first high-temperature durable layer and the second high-temperature durable layer each independently contain lead lanthanum titanate (PLT), strontium ruthenate (SRO), lanthanum nickelate (LNO), or lead titanate (PT). As a result, good adhesion between the first electrode and the second electrode and the respective high-temperature durable layers can be obtained. Further, by preventing deterioration such as oxygen defects of the electromechanical conversion layer at the time of continuous driving as a buffer layer with the electromechanical conversion layer, polarization can be maintained and a decrease in the residual polarization Pr can be prevented.

As the metal oxide, it is preferable to select and use a material used as a seed layer of PZT of the electromechanical conversion layer or a buffer layer of an orientation control layer. Due to high affinity with the PZT layer, the bonding state at the interface is good and high adhesion is obtained. Therefore, there is no mechanical loss at the time of vibration, and there is no electrical loss in the exchange of electric charges, and thus the element functions without impairing durability and element performance. Although not clearly understood, it is considered that the presence of the first high-temperature durable layer and the second high-temperature durable layer can alleviate an oxygen defect or the like caused by an interaction at an interface between the first and second electrodes during driving of PZT, and deterioration during driving can be suppressed.

Furthermore, it is preferable that the metal oxide have a lower relative dielectric constant than PZT. This makes it possible to reduce the capacitance of all the layers sandwiched between the electrodes of the electromechanical conversion element, as compared with a case where only the electromechanical conversion layer is provided. In addition, since the displacement current generated at the time of pulse driving is reduced, the heat generation or the like is reduced, and the load is reduced. In addition, since the exchange of charges is reduced, an effect of suppressing deterioration of the interface or the like is expected. Therefore, the load at the time of driving is reduced, which is advantageous in driving for a long time and can suppress deterioration.

That is, it is preferable that the relative dielectric constants of the first high-temperature durable layer and the second high-temperature durable layer are both smaller than the relative dielectric constant of the electromechanical conversion layer.

The measurement of the relative dielectric constant is performed at 20° C., and an impedance analyzer 4194A manufactured by Yokogawa-Hewlett-Packard Company is used as a measuring device. The capacitance is measured under the conditions of 1 kHz and 1 V, and the relative dielectric constant can be obtained by conversion using the area and thickness of the element.

It is not essential that the first and second high-temperature durable layers are insulators, and a conductive metal oxide may be selected.

Since both the first high-temperature durable layer and the second high-temperature durable layer have low piezoelectric performance, the amount of displacement decreases when they are formed thick. Therefore, the thicknesses of the first high-temperature durable layer and the second high-temperature durable layer are preferably within a range of 0.05 to 0.5 μm and more preferably within a range of 0.1 to 0.3 μm.

The first high-temperature durable layer and the second high-temperature durable layer are also referred to as a seed layer or a buffer layer. The first high-temperature durable layer is provided between the electromechanical conversion layer and the first electrode, and the second high-temperature durable layer is provided between the electromechanical conversion layer and the second electrode. The first high-temperature durable layer and the second high-temperature durable layer also have a role of improving the adhesiveness between the electromechanical conversion layer and the electrodes.

Both the seed layer and the buffer layer basically serve to improve the adhesion and promote the crystal growth of the piezoelectric material. In general, the seed layer is thin and mainly serves to improve the adhesion, and the orientation is such that a metal oxide is deposited in the form of islands on the layer surface and serves as nuclei for the oriented growth. The buffer layer itself has an orientation property in order to more accurately control the orientation growth of the piezoelectric material as an orientation control layer.

In particular, the first high-temperature durable layer plays a very important role in controlling the orientation of the electromechanical conversion layer. By using the optimum first high-temperature durable layer, the orientation of the (101) plane, the (111) plane, and the like can be reduced.

The high-temperature durable layer may have a laminated configuration instead of a single layer. Since LNO and SRO are metal oxides having conductivity, a configuration in which LNO is formed on the first electrode and PLT is laminated thereon also functions as a high-temperature durable layer. In this case, since the PLT can further exert the function as the buffer layer, it contributes to the satisfactory crystal orientation of the piezoelectric material thin layer. Similarly, the second high-temperature durable layer may have a laminated structure in which a layer in contact with the second electrode is a conductive metal oxide layer.

Alternatively, a stacked-layer structure of an insulator and a conductive metal oxide can be employed.

[First Electrode and Second Electrode]

The first electrode 3 and the second electrode 7 are provided so as to sandwich the electromechanical conversion layer 5 in the thickness direction. The first electrode 3 and the second electrode 7 are made of a known conductive material, and are preferably layers made of, for example, platinum (Pt), platinum (Pt), and titanium (Ti).

A thickness of the Ti layer is, for example, about 0.02 μm, and a thickness of the Pt layer is, for example, about 0.1 to 0.2 μm. Note that a layer made of iridium (Ir) may be formed instead of the Pt layer.

[Substrate]

The substrate can be configured by a semiconductor substrate made of a single crystal Si (silicon) alone having a thickness of, for example, about 250 to 750 μm or an SOI (Silicon on Insulator) substrate. The substrate may be formed of another material, but is preferably formed of a Si substrate or a silicon on insulator (SOI) substrate.

[Other Layers]

In addition to the layers described above, other layers such as an intermediate layer can be provided as necessary, for example, in order to increase adhesion.

<<Method for Manufacturing Electromechanical Conversion Element>>

A method of manufacturing an electromechanical conversion element according to the present invention includes an electromechanical conversion layer forming step of forming an electromechanical conversion layer on a first high-temperature durable layer, and in the electromechanical conversion layer forming step, a step of heating the electromechanical conversion layer to 500° C. or higher and then cooling the electromechanical conversion layer to 300° C. or lower is repeated twice or more to form the electromechanical conversion layer.

[Electromechanical Conversion Layer]

The present invention is characterized in that, in order to form an electromechanical conversion layer having a predetermined thickness, layer formation is performed dividedly. The thickness of each layer need not be evenly distributed. However, when the ratio of the thicknesses of the respective layers is extremely changed, there is a possibility that a difference occurs in the crystal growth in the thickness direction, and therefore, attention is required.

In general, in a layer formation method in which crystal growth is performed while a substrate is heated, when a thick layer is continuously deposited, the crystal growth is affected and disturbed by the change inside the apparatus, in particular, a temperature change. Therefore, orientation of (101) plane or the like, which is a hetero phase, is likely to occur. When the thickness is large, the layer-forming time becomes long, so that this tendency is likely to appear. In addition, in a case where layer formation is performed at once while heating the substrate and then the substrate is taken out, the layer stress during the layer formation is released at once. Therefore, cracks are generated and a layer having a large internal stress is formed.

In contrast, when the divided layer formation is performed, since the crystal growth of each layer is less likely to be affected by the fluctuation in the apparatus, there is no growth of hetero phases, and a satisfactory crystal growth state of a single phase can be formed. Further, by heating at 500° C. or more, growth of the (001) plane can be formed. Further, a cooling step is performed to release the stress accumulated inside the layer.

As a method performed without impairing the piezoelectric properties, a step of heating the electromechanical conversion layer to 500° C. or higher and then cooling the electromechanical conversion layer to 300° C. or lower is required. By forming the layer at a high temperature, polarization occurs during the layer formation. However, it is considered that there is an effect that the polarization can be fixed by cooling to 300° C. or less, lower temperature than the Curie point in the case of PZT.

In addition, from the viewpoint of improving reliability when formed into a device, it is more preferable to include a washing process in the case of performing divided layer formation. In the washing step, it is preferable to perform washing for each layer formation.

In the case where a solution is used for the washing, an alkaline washing agent, for example, Clean Ace manufactured by Sibata Scientific Technology Ltd. is used, and foreign substances that has been mixed during layer formation are removed by a washing method mainly including physical washing such as washing with a brush. Thus, a defect in a removed portion can be filled in the next deposition. In a case where a predetermined layer formation is performed at a time, when a foreign substance mixed during the layer formation falls off after the layer formation, a void part is generated and an effective thickness of the portion becomes thin. In that case, a leakage current flows when a voltage is applied, and element destruction occurs. Since at least the minimum effective thickness can be secured by performing the divided layer formation, the reliability of the element can be secured on a high level.

To be specific, for example, while the first high-temperature durable layer provided on the substrate is heated to a temperature of 580° C., high-frequency electric power of 2000 W is applied to form the electromechanical conversion layer having a predetermined layer thickness. When the desired thickness is, for example, 3.0 μm, and when the layer formation is divided once (in the case of dividing the electromechanical conversion layer into two layers), layer formation of 1.5 μm is first performed, and then the resultant is cooled to at least 300° C. or lower and then taken out of the chamber. Thereafter, in order to remove a foreign substance at the time of layer formation, it is preferable to perform wet scrubbing cleaning using a brush or a waste cloth and to sufficiently dry the substrate after rinsing. The substrate is put into the chamber again, and layer formation is performed under the first layer formation conditions. By further stacking a layer of 1.5 μm similarly, the electromechanical conversion layer having a thickness of 3.0 μm can be thus completed. Note that in the case of performing layer formation divided twice or more, similarly, the substrate is taken out after layer formation to a predetermined thickness, and washing is performed. Furthermore, by repeating the same cycle, an electromechanical conversion layer having a total thickness of 3.0 μm is completed. Note that the divided thicknesses can be changed as appropriate.

[First High-Temperature Durable Layer and Second High-Temperature Durable Layer]

The first high-temperature durable layer is formed on the first electrode, and it is preferable that lead lanthanum titanate (PLT), strontium ruthenate (SRO), lanthanum nickelate (LNO), lead titanate (PT), or the like be used therefor. The first high-temperature durable layer has a function as a seed layer for crystal orientation of the electromechanical conversion layer formed thereon or a function as an orientation control layer as a buffer layer that controls the orientation. Layer formation conditions and the like are adjusted so that the (001) plane of the electromechanical conversion layer is preferentially oriented. The thickness is 0.05 to 0.3 μm, and preferably has orientation or is 0.1 to 0.2 μm.

The second high-temperature durable layer is formed on the electromechanical conversion layer, and it is preferable that lead lanthanum titanate (PLT), strontium ruthenate (SRO), lanthanum nickelate (LNO), lead titanate (PT), or the like be used independently of the first high-temperature durable layer. The second high-temperature durable layer is preferably an oriented layer, but is selected, unlike the first high-temperature durable layer, in consideration of the interaction such as the adhesion with the electromechanical conversion layer and the second electrode or the diffusion of the layer interface rather than orientation.

The first high-temperature durable layer and the second high-temperature durable layer can be formed by a well-known method, for example, a method such as a vapor deposition method or a sputtering method.

[First Electrode and Second Electrode]

The first electrode is made of a conductive material, and can be formed, for example, by using a platinum (Pt) target and applying high-frequency electric power of 200 W for 12 minutes while heating the target to 400° C. on the substrate in argon gas of 1 Pa vacuum.

The second electrode can also be formed on the second high-temperature durable layer in the same manner as the first electrode.

<<Liquid Ejection Head>>

Next, a liquid ejection head provided with the electromechanical conversion element of the present invention will be described.

FIG. 4 is an example of a cross-sectional view of a liquid ejection head of the present invention. FIG. 4 shows a liquid ejection head in which a plurality of nozzles are arranged in parallel.

The liquid ejection head of the present invention includes a nozzle 52 that ejects ink droplets as a liquid, a pressure chamber 51 with which the nozzle 52 communicates, and an ejection driving means that raises the pressure of the liquid in the pressure chamber. The ejection driving means is an electromechanical conversion element 62 including a vibration plate 55 that forms a part of a substrate (wall substrate) 54 of the pressure chamber 51. The pressure chamber 51 is formed by removing a part of the substrate 54 by etching from the rear surface and bonding a nozzle plate 53 provided with the nozzle 52 to the substrate 54.

The electromechanical conversion element 62 is formed in such a manner that the vibration plate 55, the adhesive layer 56, the first electrode 57, the first high-temperature durable layer 58, the electromechanical conversion layer 59, the second high-temperature durable layer 60, and the second electrode 61 are sequentially stacked on the substrate (wall substrate) 54 and then patterned by photolithography.

The liquid ejection head manufactured in this manner can be manufactured with a simple manufacturing process. In addition, since the liquid ejection head includes the electromechanical conversion element according to the present invention having performance equivalent to that of bulk ceramics, favorable ejection characteristics can be obtained. The liquid ejection head can be suitably used as an inkjet head that ejects an inkjet ink.

In the drawings, a liquid supplying means that supplies liquid such as ink to the pressure chamber, a channel, a fluid resistance set in the channel, and the like are omitted.

<<Image Recording Apparatus>>

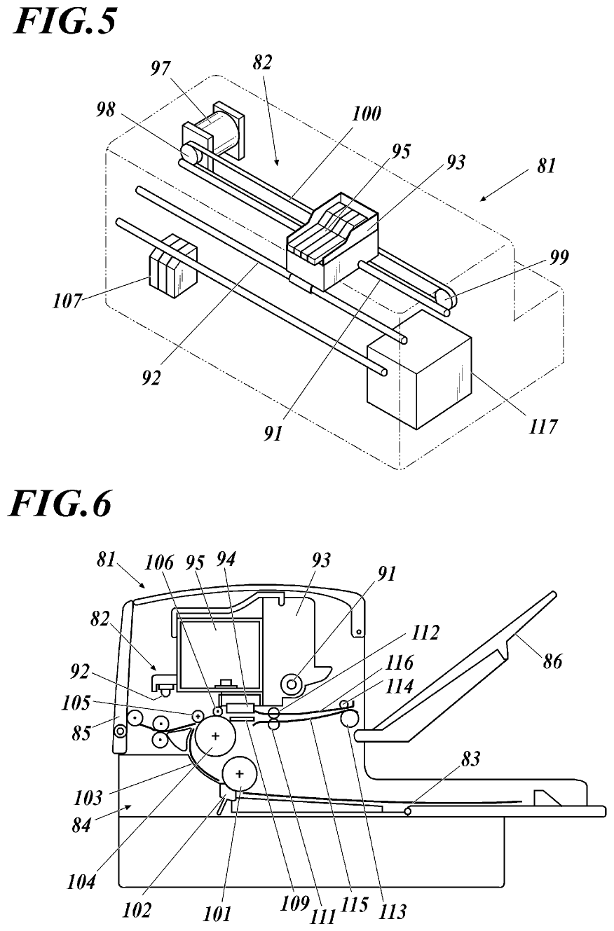

Next, an example of an image recording apparatus on which the liquid ejection head of the present invention is mounted will be described with reference to FIGS. 5 and 6. FIG. 5 is a perspective view of the image recording apparatus. FIG. 6 is a side view of a mechanism part of the image recording apparatus.

The image recording apparatus 81 accommodates a carriage which can move in the main scanning direction, a liquid ejection head 94 which is mounted on the carriage and where the present invention is applied, a printing mechanism 82 which is configured with an ink cartridge 95 that supplies ink to the liquid ejection head 94, and the like, inside a main body. In the image recording apparatus 81, a sheet feed cassette 84 in which a large number of sheets 83 can be loaded from the front side can be detachably attached to a lower portion of the main body 81. The sheet feed cassette may be a sheet feed tray. Furthermore, the image recording apparatus 83 can open a manual sheet feed tray 85 for manually feeding a sheet 83. The image recording apparatus 83 takes in the sheet 83 fed from the sheet feed cassette 84 or the manual sheet feed tray 85, records a required image with the printing mechanism 82, and then discharges the sheet to the sheet ejection tray 86 mounted on the rear surface side.

The printing mechanism 82 holds a carriage 93 slidably in the main scanning direction with a main guide rod 91 and a sub guide rod 92 which are guide members laterally bridged between right and left side plates (not shown). In the carriage 93, the liquid ejection heads 94 according to the present invention that ejects ink droplets of each color of yellow (Y), cyan (C), magenta (M), and black (Bk) are arranged in a direction such that a plurality of nozzles intersect the main scanning direction. The carriage 93 is mounted such that the ink droplet is ejected in a downward direction. In addition, ink cartridges 95 for supplying respective color inks to the liquid ejection heads 94 are replaceably mounted on the carriage 93.

### Example

Hereinafter, the present invention will be specifically described with reference to Examples, but the present invention is not limited thereto. In Examples, “part (s)” or “%” means “part (s) by mass” or “% by mass” unless otherwise specified.

### Example 1

<<Production of Electromechanical Conversion Element>>

The electromechanical conversion element was produced by sequentially forming the first electrode, the first high-temperature durable layer, the electromechanical conversion layer, the second high-temperature durable layer, and the second electrode on the substrate by a sputtering method.

<Manufacture of Electromechanical Conversion Element 1-1>

(Formation of First Electrode)

The first electrode was formed by using an Ir target, heating the substrate (silicon wafer) to 350° C. in an argon-oxygen mixture gas at a vacuum of 1 Pa, and applying direct-current power from the 800 W. The first electrode was formed to a thickness of 100 mm

(Formation of First High-Temperature Durable Layer)

The first high-temperature durable layer was formed using a PLT target having a perovskite-type structure of a metal oxide containing at least lead (Pb), lanthanum (La), and titanium (Ti). The metal oxide was composed of (PbLa) TiO₃ in which Pb at the A site was substituted with 10% La. Then, while the substrate was heated to 550° C. in an argon-oxygen mixture gas at a vacuum of 1 Pa, an RF power of 2000 W was applied to form the first high temperature durable layer on the first electrodes. The first high temperature durable layer was formed to a thickness of 100 nm.

PLT had an excessive lead composition in which Pb was more than the stoichiometric composition by 5%, and the relative dielectric constant in a case of being formed under the above conditions was 180.

(Formation of Electromechanical Conversion Layer)

The electromechanical conversion layer was formed on the first high-temperature durable layer using a sputtering apparatus. As the target, a sintered body target of PZT having a higher Pb content than the stoichiometric composition was used. In the PZT, a composition ratio of zirconium (Zr) to titanium (Ti) entering the B site is Zr/Ti=52/48, and Pb entering the A site is excessive by 20 mol %. Then, while heating the substrate to a temperature of 580° C. in an argon-oxygen mixed atmosphere at a vacuum degree of 0.5 Pa, a high-frequency electric power of 2000 W was applied to form a layer, thereby completing an electromechanical conversion layer of 3.0 μm.

The PZT had an excess lead composition in which Pb was 5% more than the stoichiometric composition, and the composition ratio of Zr to Ti was 52/48, which was the same as that of the target. The relative dielectric constant when formed under the aforementioned conditions was 950.

(Formation of Second High-Temperature Durable Layer)

The second high-temperature durable layer was formed using a PLT target having a perovskite-type structure of a metal oxide containing at least lead (Pb), lanthanum (La), and titanium (Ti). The metal oxide was composed of (PbLa) TiO₃ in which Pb at the A site was substituted with 10% La. Next, in a gas mixture of argon and oxygen under a vacuum of 1 Pa, the substrate on which the layers up to the electromechanical conversion layer had been formed was heated to 550° C. and an RF power of 2000 W was applied thereto in the same manner as for the first high-temperature durable layer, thereby forming a layer having a thickness of 200 nm.

(Formation of Second Electrode)

The second electrode was formed on the second high-temperature durable layer by using a Cu target and applying direct-current power of 1000 W in argon gas at a vacuum of 0.5 Pa. The second electrode was formed to a thickness of 1000 nm.

In the layer formation of the electromechanical conversion layer, a layer having a objective thickness of 3.0 lam was continuously formed under the above-described layer formation conditions to complete the layer formation.

In this way, an electromechanical conversion element 1-1 was prepared.

<Manufacture of Electromechanical Conversion Elements 2-1 to 4-1>

In the production of the electromechanical conversion layer in the electromechanical conversion element 1-1, a layer was not formed at once to the objective thickness, but was formed to a desired thickness. Thereafter, the substrate temperature was once lowered to room temperature (20° C.), and then the aforementioned washing and drying were performed. Next, layer formation was performed in a cycle of heating and layer formation, cooling, and washing and drying in this order to form an electromechanical conversion layer having the same thickness in total. Other than that, electromechanical conversion elements 2-1 to 4-1 were produced in the same manner as the electromechanical conversion element 1-1.

In the electromechanical conversion element 2-1, a total thickness of 3.0 lam was equally divided into two layers and deposited. Such layer formation is referred to as 1-division layer formation. Specifically, in the case of the 1-division layer formation, first, a layer with a thickness of 1.5 μm was formed, cooled to 20° C., and then taken out from the chamber. Thereafter, in order to remove foreign substance at the time of layer formation, wet rubbing washing using a brush was performed. A 5% diluted solution of Clean Ace (manufactured by AS ONE Corporation), an alkali-based washing liquid, was used as a washing liquid, and after washing, the substrate was rinsed with pure water and then sufficiently dried. After that, the substrate was put into the chamber again, and film formation was performed under the first layer formation conditions. An electromechanical conversion layer having a thickness of 3.0 μm was completed by additionally laminating a layer of 1.5 μm in the same manner.

In the electromechanical conversion element 3-1, a total thickness of 3.0 μm was equally divided into three layers and deposited. This layer formation is referred to as 2-division layer formation.

In the electromechanical conversion element 4-1, a total thickness of 3.0 μm was equally divided into four layers and deposited. This layer formation is referred to as 3-division layer formation.

<Manufacture of Electromechanical Conversion Element 5-1)

In the production of the electromechanical conversion element 1-1, only the electromechanical conversion layer was formed between the first electrode and the second electrode without forming the first and second high-temperature durable layers. Other than that, an electromechanical conversion element 5-1 was produced in the same manner as the production of the electromechanical conversion element 1-1.

For each of the electromechanical conversion elements 1-1 to 5-1, a total of three electromechanical conversion elements, i.e., two electromechanical conversion elements each, were produced under the same conditions as in the production of each of the electromechanical conversion elements.

That is, a total of fifteen electromechanical conversion elements were produced, that is, the electromechanical conversion elements 1-1 to 1-3, 2-1 to 2-3, 3-1 to 3-3, 4-1 to 4-3, and 5-1 to 5-3.

[Evaluation of Orientation Degree]

XRD measurement was performed on the obtained fifteen electromechanical conversion elements.

Specifically, the degree of orientation was evaluated by Out-of-plane Measurement: measurement angle range 10-110° (001)-(004) using an X-ray diffraction apparatus RINT-TTR III manufactured by Rigaku Corporation. In a case where the diffraction peak intensities of the (001) plane, the (101) plane, and the (111) plane were respectively set to I(001), I(101), and I(111), the degree of orientation of (001) plane represented by {I(001)/(I(001)+I(101)+I(111))}×100% was evaluated. The results are shown in TABLE I.

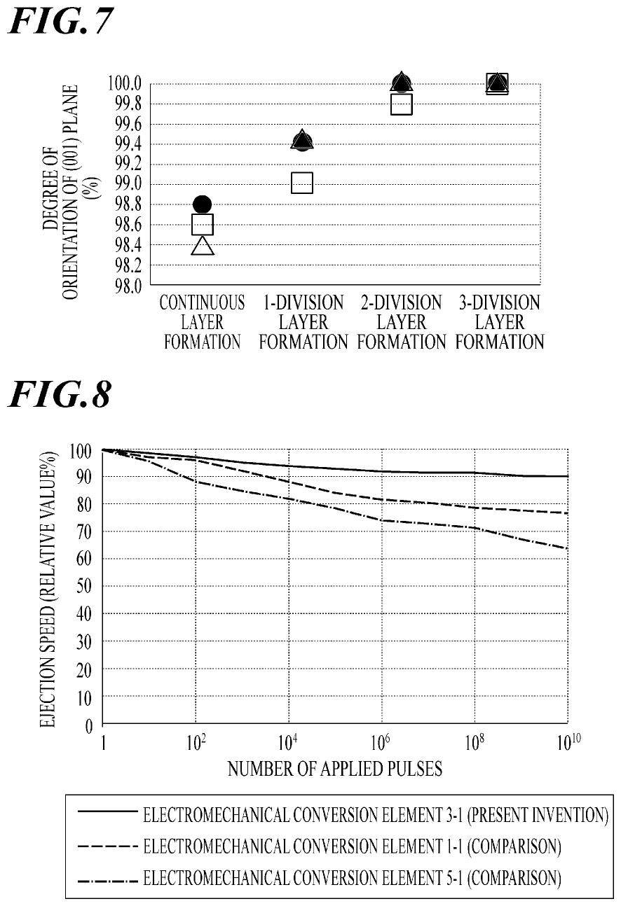

In addition, FIG. 7 shows the number of heating and cooling cycles (divided layer formation) of the electromechanical conversion layer and the degree (%) of orientation of (001) plane in the XRD measurement. In the drawing, ● indicates the degree of orientation of the electromechanical conversion element *−1, □ indicates the degree of orientation of the electromechanical conversion element *−2, and Δ indicates the degree of orientation of the electromechanical conversion element *−3. * represents 1 to 4.

The peak intensities of the (001) plane, the (101) plane, and the (111) plane of the electromechanical conversion elements 1-1, 2-1, 3-1, 4-1, and 5-1 are shown in detail in TABLE II below.

TABLE I

| ELECTROMECHANICAL | | 1-1 | 1-2 | 1-3 | 2-1 | 2-2 | 2-3 | 3-1 | 3-2 | 3-3 |
|---|---|---|---|---|---|---|---|---|---|---|
| CONVERSION | | | | | | | | | | |
| ELEMENT No. | | | | | | | | | | |
| PRESENCE OR ABSENCE OF | | PRESENT | | | PRESENT | | | PRESENT | | |
| FIRST HIGH-TEMPERATURE | | | | | | | | | | |
| DURABLE LAYER | | | | | | | | | | |
| PRESENCE OR ABSENCE OF | | PRESENT | | | PRESENT | | | PRESENT | | |
| SECOND HIGH-TEMPERATURE | | | | | | | | | | |
| DURABLE LAYER | | | | | | | | | | |
| ELECTROMECHANICAL | LAYER | CONTINUOUS | | | 1-DIVISION | | | 2-DIVISION | | |
| CONVERSION LAYER | FORMING | LAYER | | | LAYER | | | LAYER | | |
| | METHOD | FORMATION | | | FORMATION | | | FORMATION | | |
| | DEGREE OF | 98.8 | 98.6 | 98.4 | 99.4 | 99.0 | 99.4 | 100.0 | 99.8 | 100.0 |

ORIENTATION OF
(001) PLANE
(%)

| | | | | | | | | | |
|---|---|---|---|---|---|---|---|---|---|
| REMARKS | *2 | *2 | *2 | *1 | *1 | *1 | *1 | *1 | *1 |

| ELECTROMECHANICAL | | 4-1 | 4-2 | 4-3 | 5-1 | 5-2 | 5-3 |
|---|---|---|---|---|---|---|---|
| CONVERSION ELEMENT | | | | | | | |
| No. | | | | | | | |
| PRESENCE OR ABSENCE OF | | PRESENT | | | ABSENT | | |
| THIRD HIGH-TEMPERATURE | | | | | | | |
| DURABLE LAYER | | | | | | | |
| PRESENCE OR ABSENCE OF | | PRESENT | | | ABSENT | | |
| FOURTH HIGH-TEMPERATURE | | | | | | | |
| DURABLE LAYER | | | | | | | |
| ELECTROMECHANICAL | LAYER FORMING | 3-DIVISION | | | CONTINUOUS | | |
| CONVERSION LAYER | METHOD | LAYER | | | LAYER | | |
| | | FORMATION | | | FORMATION | | |
| | DEGREE OF | 100.0 | 100.0 | 10.0 | 97.5 | 98.0 | 912 |
| | ORIENTATION OF | | | | | | |
| | (001) PLANE | | | | | | |
| | (%) | | | | | | |

| | | | | | | |
|---|---|---|---|---|---|---|
| REMARKS | *1 | *1 | *1 | *2 | *2 | *2 |

*1: PRESENT INVENTION
*2: COMPARATIVE EXAMPLE

TABLE II

| ELECTROMECHANICAL | | 1-1 | 2-1 | 3-1 | 4-1 | 5-1 |
|---|---|---|---|---|---|---|
| CONVERSION ELEMENT | | | | | | |
| No. | | | | | | |
| PRESENCE OR ABSENCE OF | | PRESENT | PRESENT | PRESENT | PRESENT | ABSENT |
| FIRST HIGH-TEMPERATURE | | | | | | |
| DURABLE LAYER | | | | | | |
| PRESENCE OR ABSENCE OF | | PRESENT | PRESENT | PRESENT | PRESENT | ABSENT |
| SECOND HIGH-TEMPERATURE | | | | | | |
| DURABLE LAYER | | | | | | |
| ELECTROMECHANICAL | LAYER FORMING | CONTINUOUS | I-DIVISION | 2-DMISION | 3-DMISION | CONTINUOUS |
| CONVERSION LAYER | METHOD | LAYER | LAYER | LAYER | LAYER | LAYER |
| | | FORMATION | FORMATION | FORMATION | FORMATION | FORMATION |
| | PEAK INTENSITY OF | 59724 | 68265 | 76051 | 65193 | 49240 |
| | (001) PLANE | | | | | |
| | [cps] | | | | | |
| | PEAK INTENSITY OF | 730 | 396 | 0 | 0 | 677 |
| | (001) PLANE | | | | | |
| | [cps] | | | | | |
| | PEAK INTENSITY OF | 0 | 0 | 0 | 0 | 575 |
| | (111) PLANE | | | | | |
| | [cps] | | | | | |
| | DEGREE OF | 98.8 | 99.4 | 100.0 | 100.0 | 97.5 |
| | ORIENTATION OF | | | | | |
| | (001) PLANE | | | | | |
| | (%) | | | | | |

| | | | | | |
|---|---|---|---|---|---|
| REMARKS | *2 | *1 | *1 | *1 | *2 |

*1: PRESENT INVENTION
*2: COMPARATIVE EXAMPLE

As can be seen from the electromechanical conversion elements 1-1 to 4-3 in TABLE I, since a degree of orientation of 99.0% or more is obtained by performing the divided layer formation, it is understood that an electromechanical conversion layer having a high degree of orientation can be produced. In addition, in the electromechanical conversion elements 5-1 to 5-3 which do not have the first and second high-temperature durable layers, it is understood that both the components of the hetero-phase and the diffraction intensity increase, and the degree of orientation of the (001) plane decreases.

### Example 2

(Temperature Dependence of Residual Polarization)

FIG. 3 shows the temperature dependence of the residual polarization of the electromechanical conversion elements of the electromechanical conversion element 2-1 (the present invention) and the electromechanical conversion element 5-1 (a comparative example) measured by the above-described method. The electromechanical conversion element of the present invention has a larger residual polarization even at a high temperature of 50° C. than at room temperature. Furthermore, the residual polarization at 85° C. also has a higher value than that at room temperature and satisfies Expression 2 described above.

As described above, since the decrease in the residual polarization at the time of high-temperature driving is small, it is found that the deterioration of the piezoelectric characteristics is suppressed even under the high-temperature driving condition, and the decrease in the displacement amount of the piezoelectric material over time is suppressed.

### Example 3

[Production of Actuator and Inkjet Head]

An actuator was prepared by forming a vibration plate and a pressure chamber using each of the prepared electromechanical conversion elements 1-1 (comparative example), 3-1 (present invention), and 5-1 (comparative example). Furthermore, the channel substrate and the nozzle plate were bonded together, thus producing the liquid ejection head illustrated in FIG. 4 as an inkjet head.

(Evaluation of Electrostatic Capacitance of One Element of Actuator)

The electrostatic capacitance of one element of the actuator corresponding to each nozzle was measured. The electrostatic capacitances for one element of the actuators corresponding to the electromechanical conversion elements 1-1, 3-1, and 5-1 were 200 pF, 195 pF, and 285 pF, respectively.

(Continuous Drive Pulse Drive Durability Test)

Inkjet heads including the electromechanical conversion elements 1-1 (comparative), 3-1 (present invention), and 5-1 (comparative) were mounted on the image forming apparatuses illustrated in FIGS. 5 and 6. Under a high temperature environment of 50° C., the waveform was adjusted such that the initial speed was 7 msec, and a pulse drive durability test of 60 kHz was performed. FIG. 8 is a graph illustrating a relationship between the number of applied pulses and an ejection speed (a relative value with respect to an initial speed) when a drive voltage of 10 billion pulses is applied to each of the inkjet heads.

As is clear from FIG. 8, it is understood that a decrease over time in the ejection speed when the electromechanical conversion element 3-1 is used in an inkjet head and continuous ejection is performed under a high-temperature environment is suppressed.

### INDUSTRIAL APPLICABILITY

The electromechanical conversion element of the present invention is suitably used for a liquid ejection head that ejects an inkjet ink because a decrease in the amount of displacement of the piezoelectric material over time is suppressed when the electromechanical conversion element is continuously pulse-driven for a long period of time in a high-temperature environment.

### REFERENCE SIGNS LIST

1 electromechanical conversion element
2 substrate
3 first electrode
4 first high-temperature durable layer
5 electromechanical conversion layer
6 second high-temperature durable layer
7 second electrode
51 pressure chamber
52 nozzle
53 nozzle plate
54 substrate (wall substrate)
55 vibration plate
56 adhesive layer
57 first electrode
58 first high-temperature durable layer
59 electromechanical conversion layer
60 second high-temperature durable layer
61 second electrode
62 electromechanical conversion element
81 image recording apparatus
82 printing mechanism
83 sheet
84 sheet feed cassette
85 manual sheet feed tray
86 sheet ejection tray
91 main guide rod
92 sub guide rod
93 carriage
94 liquid ejection head
95 ink cartridge
97 main scanning motor
98 driving pulley
99 driven pulley
100 timing belt
101 sheet feed roller
102 friction pad
103 guide member
104 conveyance roller
105 conveyance roller
106 leading end roller
107 sub-scanning motor
109 print receiving member
111 conveyance roller
112 spur
113 sheet ejection roller
114 spur
115, 116 guide member

1. An electromechanical conversion element comprising:
a first electrode, an electromechanical conversion layer, and a second electrode provided on a substrate;
a first high-temperature durable layer that contains a metal oxide between the first electrode and the electromechanical conversion layer; and
a second high-temperature durable layer that containing a metal oxide between the electromechanical conversion layer and the second electrode,
wherein the electromechanical conversion layer contains a perovskite-type crystal, and
upon diffraction peak intensities of a (001) plane, a (101) plane, and a (111) plane in X-ray diffraction measurement of the electromechanical conversion layer being I(001), I(101), and I(111), respectively, a degree of orientation of the (001) plane represented by {I(001))/(I(001)+I(101)+I(111)}×100% is 99.0% or more.

2. The electromechanical conversion element according to claim 1, wherein metal oxides contained in the first high-temperature durable layer and the second high-temperature durable layer each independently contain lanthanum lead titanate (PLT), strontium ruthenate (SRO), lanthanum nickelate (LNO), or lead titanate (PT).

3. The electromechanical conversion element according to claim 1, wherein the perovskite type crystal contains lead zirconate titanate (PTZ).

4. The electromechanical conversion element according to claim 1, wherein, upon a residual polarization at 50° C. being denoted by Pr(50° C.) [μC/cm²] and a residual polarization at 20° C. being denoted by Pr(20° C.) [μC/cm²], Expression 1 is satisfied:
Pr(50° C.)/Pr(20° C.)≥1.00. (Expression 1):

5. The electromechanical conversion element according to claim 1, wherein, upon a residual polarization at 85° C. being denoted by Pr(85° C.) [μC/cm²] and a residual polarization at 20° C. being denoted by Pr(20° C.) [μC/cm²], Expression 2 is satisfied:
Pr(85° C.)/Pr(20° C.)≥0.90. (Expression 2):

6. The electromechanical conversion element according to claim 1, wherein relative dielectric constants of the first high-temperature durable layer and the second high-temperature durable layer are both smaller than a relative dielectric constant of the electromechanical conversion layer.

7. A method of manufacturing the electromechanical conversion element according to claim 1, comprising:
forming an electromechanical conversion layer on the first high-temperature durable layer, and
in the forming of the electromechanical conversion layer, heating the electromechanical conversion layer to 500° C. or higher and then cooling the electromechanical conversion layer to 300° C. or lower is repeated twice or more to form the electromechanical transducer layer.

8. A liquid ejection head comprising the electromechanical conversion element according to claim 1.
